(19) United States
(12) Patent Application Publication
(10) Pub. No.: US 2025/0380403 A1
(43) Pub. Date: Dec. 11, 2025

(54) SEMICONDUCTOR DEVICE AND METHOD OF MANUFACTURING THE SAME

(71) Applicant: Samsung Electronics Co., Ltd., Suwon-si (KR)

(72) Inventor: Moonju HONG, Suwon-si (KR)

(21) Appl. No.: 19/189,445

(22) Filed: Apr. 25, 2025

(30) Foreign Application Priority Data
Jun. 5, 2024 (KR) 10-2024-0073993

(51) Int. Cl. H10B 12/00

(52) U.S. Cl. CPC H10B 12/33; H10B 12/05

(57) ABSTRACT

A semiconductor device is provided. The semiconductor device includes a bit line extending in a first direction parallel to a substrate, a first channel pattern connected to the bit line and disposed perpendicular to the substrate, a gate insulating pattern disposed on the first channel pattern, a word line disposed on the gate insulating pattern and extending in a second direction that is parallel to the substrate and perpendicular to the first direction, data storage patterns spaced apart from each other in the first direction and the second direction, storage node contacts, each of which disposed on a corresponding one of the data storage patterns, and a mold pattern extending in the second direction and configured to support the first channel pattern. The mold pattern includes a conductive sub-mold pattern.

### CROSS-REFERENCE TO RELATED APPLICATION

This application claims the benefit of Korean Patent Application No. 10-2024-0073993, filed on Jun. 5, 2024, in the Korean Intellectual Property Office, the entire disclosure of which is incorporated herein by reference for all purposes.

### BACKGROUND

### 1. Field of the Invention

The following embodiments relate to a semiconductor device and a method of manufacturing the semiconductor device.

### 2. Description of the Related Art

Technology of manufacturing semiconductor devices has been developed to increase the integration density, operation speeds, and yields of semiconductor devices. To enhance the integration density, operation speed, or current drive capability of a transistor, a semiconductor device including a vertical channel transistor (VCT) has been proposed.

In the semiconductor device including the vertical channel transistor (VCT), a contact that connects a channel pattern and a bit line BL may be formed.

### SUMMARY

One or more embodiments provide a semiconductor device with enhanced electrical characteristics and reliability.

According to an aspect, a semiconductor device includes a bit line extending in a first direction parallel to a substrate, a first channel pattern connected to the bit line and disposed perpendicular to the substrate, a gate insulating pattern disposed on the first channel pattern, a word line disposed on the gate insulating pattern and extending in a second direction that is parallel to the substrate and perpendicular to the first direction, data storage patterns spaced apart from each other in the first direction and the second direction, storage node contacts, each of which is disposed on a corresponding one of the data storage patterns, and a mold pattern extending in the second direction and configured to support the first channel pattern. The mold pattern includes a conductive sub-mold pattern.

According to another aspect, a method of manufacturing a semiconductor device includes preparing a storage node contact connected to a data storage pattern, forming a mold pattern positioned lengthwise in a first direction, the mold pattern comprising a conductive sub-mold pattern, forming a first channel pattern on the mold pattern, forming a gate insulating layer on the mold pattern, partially removing the gate insulating layer disposed on the mold pattern and a top surface of the first channel pattern, thereby forming a gate insulating pattern, forming a word line on the gate insulating pattern, the word line extending in a second direction which is perpendicular to the first direction, forming a second insulating layer and a third insulating layer on the word line, performing a planarization thereby partially removing the second insulating layer and the third insulating layer and exposing the top surface of the first channel pattern and the mold pattern, and forming a bit line by depositing a conductive bit line layer on the first channel pattern.

According to another aspect, a semiconductor device includes a bit line extending in a first direction parallel to a substrate, a word line extending in a second direction perpendicular to the first direction, a storage node contact connected to the word line, a data storage pattern connected to a lower portion of the storage node contact, a mold pattern extending in the second direction, the mold pattern comprising a conductive sub-mold pattern, a first channel pattern disposed on the mold pattern, and a gate insulating pattern disposed on the first channel pattern. The bit line is formed of a conductive bit line layer disposed in the first direction.

Additional aspects of embodiments will be set forth in part in the description which follows and, in part, will be apparent from the description. Other aspects of the invention may be learned by practice of the embodiments described in the disclosure.

### BRIEF DESCRIPTION OF THE DRAWINGS

These and/or other aspects, features, and advantages of the invention will become apparent and more readily appreciated from the following description of embodiments, taken in conjunction with the accompanying drawings of which:

FIG. 1 is a diagram schematically illustrating a semiconductor device according to an embodiment;

FIG. 2 is a perspective view schematically illustrating a memory cell array of the semiconductor device of FIG. 1;

FIG. 3 is a cross-sectional view illustrating an example of a semiconductor device according to an embodiment;

FIGS. 4 to 10, 11A, 11B and 11C are diagrams to describe a method of manufacturing the semiconductor device of FIG. 3;

FIG. 12 is a cross-sectional view illustrating another example of a semiconductor device according to an embodiment;

FIGS. 13 and 14 are diagrams to describe a method of manufacturing the semiconductor device of FIG. 12;

FIG. 15 is a cross-sectional view illustrating another example of a semiconductor device according to an embodiment;

FIGS. 16 to 20 are diagrams to describe a method of manufacturing the semiconductor device of FIG. 15;

FIG. 21 is a cross-sectional view illustrating another example of a semiconductor device according to an embodiment; and

FIGS. 22 to 25 are diagrams to describe a method of manufacturing the semiconductor device of FIG. 21.

### DETAILED DESCRIPTION

Hereinafter, embodiments will be described in detail with reference to the accompanying drawings. When describing the embodiments with reference to the accompanying drawings, like reference numerals refer to like components and a repeated description related thereto may be omitted.

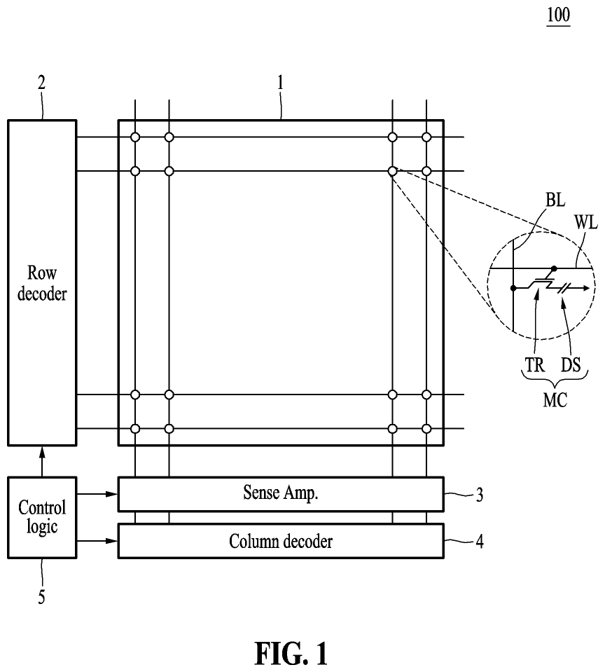

FIG. 1 is a diagram schematically illustrating a semiconductor device according to an embodiment.

A semiconductor device 100 of FIG. 1 may include a memory cell array 1, a row decoder 2, a sense amplifier 3, a column decoder 4, and a control logic 5. For example, the semiconductor device 100 may be a semiconductor memory device, and may be implemented as a dynamic random access memory (DRAM) device.

The memory cell array 1 may include a plurality of memory cells MC that are two-dimensionally or three-dimensionally arranged. For example, the memory cell array 1 may be disposed on one surface of a substrate, and a plane of the memory cell array 1 may be parallel to a plane of the substrate. Each of the memory cells MC may be connected to a word line WL and a bit line BL that cross each other.

Each of the memory cells MC may include a selection element TR and a data storage element DS. The selection element TR and the data storage element DS may be electrically connected to each other. The selection element TR may be connected to both the word line WL and the bit line BL. For example, the selection element TR may be provided at a position in which the word line WL and the bit line BL cross each other. The selection element TR may be or include, for example, a field effect transistor (FET).

The data storage element DS may be or include, for example, a capacitor, a magnetic tunnel junction pattern, or a variable resistor. For example, the data storage element DS may be any kind of capacitor (e.g., a ferroelectric capacitor) used in a one-transistor one-capacitor (1T1C) memory cell, which is a type of memory comprising one capacitor and one transistor. For example, the data storage element DS may be any kind of resistor including an MTJ (magnetic tunnel junction), a ferroelectric tunnel junction (FTJ) and combinations thereof used in a one-transistor one-resistor (1T1R) memory cell, which is a type of memory comprising one resistor and one transistor. For example, The data storage element DS may be selected from the group consisting of data storage structures (or patterns) of a phase-change memory (PCM, PRAM, PCRAM, PC-RAM), a resistive memory (RRAM), a magnitoresistive memory (MRAM), a polymer memory (PRAM), a molecular memory, a ferroelectric memory (FeRAM), an ionic memory (PMC), a memristive memory, a spin memory, an oxide memory (such as ReRAM and OxRAM), a conductive bridging random access memory (CBRAM), and combinations thereof.

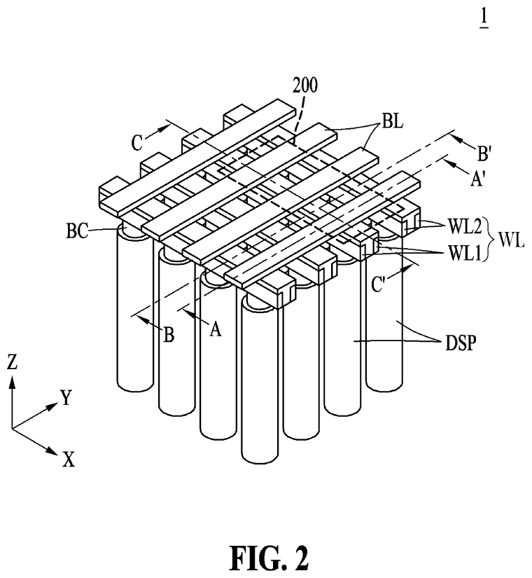

For example, the selection element TR may be a transistor, a gate electrode of the transistor may be connected to the word line WL, and a source terminal or a drain terminal of the transistor may be connected to the bit line BL or the data storage element DS. An example of a structure including the word line WL, the bit line BL, the selection element TR, and the data storage element DS of each of the memory cells MC in the memory cell array 1 will be described below with reference to FIG. 2.

FIG. 2 is a perspective view schematically illustrating the memory cell array 1 of the semiconductor device 100 of FIG. 1.

Referring to FIG. 2, the semiconductor device 100 may include a data storage pattern DSP, a storage node contact BC, word lines WL1 and WL2, and a bit line BL. The bit line BL may extend in a first direction (e.g., Y-axis direction). The word lines WL1 and WL2 may be disposed on the storage node contact BC. The word lines WL1 and WL2 may extend in the second direction (e.g., X-axis direction) perpendicular to the first direction. The first direction and the second direction may be parallel to a plane corresponding to the substrate (not shown in the drawings) or the memory cell array 1. For example, the substrate may have a shape of a plate extending along a plane defined by the first direction and the second direction. In an embodiment, a mold structure and a channel pattern may be formed on or above the storage node contact BC.

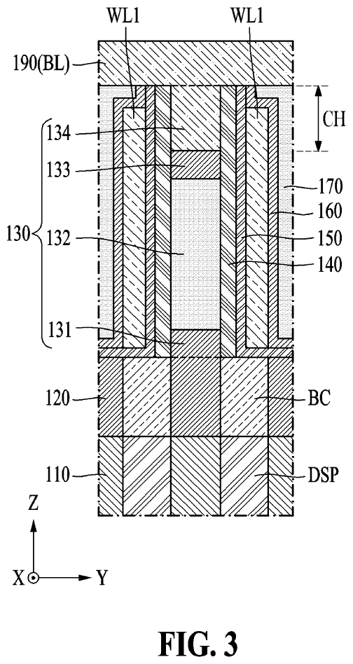

Referring to FIGS. 1 and 2, the selection element TR of each of the memory cells MC may be or include a vertical channel transistor (VCT). A lengthwise direction of a channel of the vertical channel transistor (VCT) may be perpendicular to one surface (e.g., a top surface) of the substrate. The data storage element DS of each of the memory cells MC may include or be the data storage pattern DSP. An example of a memory cell MC including a vertical channel transistor (VCT) will be described below with reference to FIG. 3.

The row decoder 2 may decode an address that is input from an external circuit or device (e.g., a host device or a memory controller located external to the semiconductor device 100). The row decoder 2 may select one of word lines WL of the memory cell array 1, based on a result obtained by decoding the address. The result (e.g., the decoded address) obtained by decoding the address in the row decoder 2 may be provided to a row driver (not shown). The row driver may separately provide predetermined voltages to the selected word line WL and unselected word lines, in response to controls of control circuits.

The sense amplifier 3 may sense, amplify, and output a difference in voltage between a reference bit line and a bit line BL that is selected based on an address decoded by the column decoder 4.

The column decoder 4 may provide a data transmission path between the sense amplifier 3 and the external circuit or device (e.g., a memory controller). The column decoder 4 may decode an externally input address to select one of bit lines BL.

The control logic 5 may generate a control signal that is used to control an operation of writing or reading data to or from a corresponding memory cell in the memory cell array 1.

For reference, the row decoder 2, the sense amplifier 3, the column decoder 4, and the control logic 5 are illustrated as being located around the memory cell array 1, however, the invention is not limited thereto. For example, a peripheral circuit including the row decoder 2, the sense amplifier 3, the column decoder 4, and the control logic 5 may be disposed on a plane different from a plane on which the memory cell array 1 is disposed. The peripheral circuit may be disposed above or below the memory cell array 1 such that, e.g., the semiconductor device has a cell over peripheral (COP) structure (or scheme). In an example, though not shown in the drawings, the peripheral circuit may be provided on the substrate, and the memory cell array 1 may be provided on the peripheral circuit. In another example, the peripheral circuit may be provided on a first substrate, and the memory cell array 1 may be provided on a second substrate. In this example, the first substrate and the second substrate may be positioned to face each other.

In FIG. 2, line A-A′ is a line in a direction (e.g., Y-axis direction) of a bit line BL of a region including a storage node contact BC, and line B-B′ is a line in a direction of a region that does not include a storage node contact BC. In addition, line C-C′ is a line in a direction of a word line WL, to represent a region including a mold structure 130 that does not include the word line WL. The mold structure 130 may extend in a second direction (e.g., X-axis direction).

For example, in FIG. 2, the Line A-A′ extends parallel to the bit line BL and is located above the bit line BL. The Line B-B′ is parallel to the axis of the bit line BL, but is not located above the bit line BL. The Line B-B′ is located above an area between a pair of bit lines (the bit lines BL and an adjacent bit line BL). The Line C-C′ extends parallel to the word line WL (i.e., WL1 or WL2). The Line C-C′ is located above an area between adjacent word lines WL.

FIG. 2 is a perspective view schematically illustrating the memory cell array 1 of FIG. 1, and illustrates a state in which a substrate, in which storage node contacts BC and data storage patterns DSP are connected, is vertically flipped. To increase an integration density and performance of a semiconductor device, the semiconductor device may be manufactured by manufacturing a substrate through a back-end-of-line (BEOL) process, flipping the substrate, and forming a cell array on a storage node contact BC. For example, the substrate may include conductive wiring layer and/or patterns, to which the storage node contacts BC and the data storage patterns DSP may be electrically connected.

In some embodiments, the memory cell array 1 may include storage node contacts BC and data storage patterns DSP, which are connected to each other. To increase an integration density and performance of the semiconductor device, wiring layers and/or wiring patterns may be formed by using a back-end-of-line (BEOL) process. Subsequently, the memory cell array 1 may be formed on the wiring layers and/or wiring patterns. In this case, the resultant structure obtained by the BEOL process may be turned over before forming the memory cell array 1. The resultant structure obtained by the BEOL process may be disposed on a peripheral circuit provided on a substrate, and the memory cell array 1 may be provided on the peripheral circuit.

Referring to FIG. 2, the semiconductor device 100 may include a data storage pattern DSP, a storage node contact BC, word lines WL1 and WL2, and a bit line BL. The bit line BL may extend in a first direction (e.g., a Y-axis direction). The word lines WL1 and WL2 may be disposed on the storage node contact BC. The word lines WL1 and WL2 may extend in the second direction (e.g., the X-axis direction) perpendicular to the first direction. The first direction and the second direction may be parallel to a plane corresponding to the substrate or the memory cell array 1. For example, the substrate may have a shape of a plate extending along a plane defined by the first direction and the second direction. In an embodiment, a mold structure and a channel pattern may be formed on or above the storage node contact BC.

Hereinafter, the semiconductor device 100 according to an embodiment is mainly described in detail with reference to FIGS. 3 to 25, which are enlarged cross sectional views illustrating a portion of the semiconductor device 1 shown in FIG. 2. The enlarged portion corresponds to a structure that has been projected vertically (in Z-axis direction) from the dotted rectangle 200, which serves as the reference plane for the projections. Components of the semiconductor device 100 that will be described below are examples to describe the technical idea of the present disclosure, and the scope of the present invention is not limited thereto.

FIG. 3 is a cross-sectional view illustrating an example of a semiconductor device according to an embodiment. FIG. 3 illustrates a cross section (e.g., a cross section corresponding to a Y-Z plane) obtained by cutting a memory cell of the semiconductor device in a direction perpendicular to a substrate along line A-A′ of FIG. 2. Line A-A′ may be parallel to a bit line BL.

The X-Y, Y-Z, and X-Z planes are formed by the intersections of pairs of the X, Y, and Z axes in three-dimensional space. For example, the X-Y plane is the intersection of the X- and Y-axes, the Y-Z plane is formed by the intersection of the Y- and Z-axes, and the X-Z plane is created by the intersection of the X- and Z-axes.

In some embodiments, the semiconductor device 100 may include a data storage pattern DSP, a storage node contact BC, a lower insulating layer 110, a first insulating layer 120, a second insulating layer 160, a third insulating layer 170, a mold structure 130, a first channel pattern 140, a gate insulating pattern 150, a second metal layer 190 (BL), and a word line WL1.

The data storage pattern DSP may be disposed on one side (e.g., a lower portion) of the storage node contact BC. The data storage pattern DSP may be electrically connected to the first channel pattern 140 through the storage node contact BC. Data storage patterns DSP may be spaced apart from each other in the first direction and the second direction. The data storage patterns DSP may be arranged in a form of a matrix (or in a repeated or regular arrangement) and may completely overlap the storage node contact BC in a direction (e.g., Z-axis direction) or partially overlap the storage node contact BC.

The data storage patterns DSP may be capacitors. Though now shown in the drawings, the data storage patterns DSP may include storage electrodes, a plate electrode, and capacitor dielectric films interposed between the storage electrodes and the plate electrode. Here, the storage electrodes may be in contact with the storage node contact BC. The storage electrodes may have various shapes, for example, a circular shape, an elliptical shape, a rectangular shape, a square shape, a rhombus shape, or a hexagonal shape.

The lower insulating layer 110 may be disposed between the data storage patterns DSP. For example, the lower insulating layer 110 may be disposed in a region defined by the data storage patterns DSP, when viewed in a direction perpendicular to the substrate. For example, the data storage patterns DSP may be arranged in a specific pattern when viewed from the second metal layer 190 (BL). In a plan view (which is cut along a X-Y plane), the arrangement of the data storage patterns DSP may be in a repeated or regular form with the lower insulating layer 110 filling in the remaining area.

The storage node contact BC may be disposed on the data storage pattern DSP. The storage node contact BC may be disposed between first insulating layers 120. The storage node contact BC may have various shapes, for example, a circular shape, an elliptical shape, a rectangular shape, a square shape, a rhombus shape, a hexagonal shape, or a polygonal shape with a predetermined thickness. When viewed in a direction (e.g., Z-axis direction) perpendicular to the substrate, the first insulating layers 120 may be disposed in a region defined by the storage node contact BC. For example, the storage node contacts BC may be arranged in a specific pattern when viewed from the second metal layer 190 (BL). In a plan view (e.g., when cut along a X-Y plane), the arrangement of the storage node contacts BC may be in the form of a specific pattern within the overall space, with the first insulating layers 120 filling in the remaining area.

The storage node contact BC may include a conductive material. The conductive material may include, for example, at least one of doped polysilicon, a conductive metal nitride, a conductive metal silicon nitride, a metal carbonitride, a conductive metal silicide, a conductive metal oxide, a two-dimensional (2D) material, a metal, or a metal alloy. In some embodiments, though not shown in the drawings, each landing pad may be disposed on a corresponding one of the storage node contacts BC.

The first insulating layer 120 may be disposed between storage node contacts BC. In some embodiments, though not shown in the drawings, the first insulating layer 120 may be disposed in an inner region of the storage node contact BC, when viewed in the direction (e.g., Z-axis direction) perpendicular to the substrate. For example, when the storage node contact BC is formed in a cylindrical shape or ring-shape (e.g., a shape of a donut), the first insulating layer 120 may be provided in an inner region the cylindrical or ring-shaped storage node contact BC (e.g., a central point of the shape of the donut). In some embodiments, though not shown in the drawings, the first insulating layer 120 may also be provided between the storage node contact BC and a landing pad. The first insulating layer 120 may include an insulating material.

The first channel pattern 140 may be connected to the bit line BL and disposed perpendicular to the substrate. The first channel pattern 140 may be disposed perpendicular to the bit line BL. For example, the first channel pattern 140 may extend in a third direction (e.g., Z-axis direction) and may be electrically connected to the storage node contact BC. The first channel pattern 140 may be disposed on a side surface of the mold structure 130.

The gate insulating pattern 150 may be disposed on the first channel pattern 140. The gate insulating pattern 150 may include an insulating material.

The word line WL1 may be disposed on the gate insulating pattern 150 and may extend in the second direction (e.g., X-axis direction).

According to an embodiment, an upper end portion of the word line WL1 may be disposed at a higher level than a lower end portion of the first metal layer 134.

The second insulating layer 160 may be disposed on an outer side surface of the word line WL1 and the gate insulating pattern 150, and may be formed of a silicon nitride.

The third insulating layer 170 may be included in a space enclosed by the second insulating layer 160. For example, the third insulating layer 170 may be disposed between two adjacent mold structures 130, and may be formed of a silicon oxide.

The mold structure 130 may protrude in the third direction (e.g., Z-axis direction) perpendicular to one surface (e.g., a top surface) of the first insulating layer 120. For example, the mold structure 130 may extend in the third direction (e.g., Z-axis direction) from the top surface of the first insulating layer 120. The mold structure 130 may be positioned lengthwise in the third direction. The third direction may be perpendicular to the first direction and the second direction. The mold structure 130 may be provided on the first insulating layer 120. For example, the mold structure 130 may be provided on at least a portion of an area, which is between storage node contacts BC. The mold structure 130 may extend in the second direction (e.g., X-axis direction) and mechanically support the first channel pattern 140.

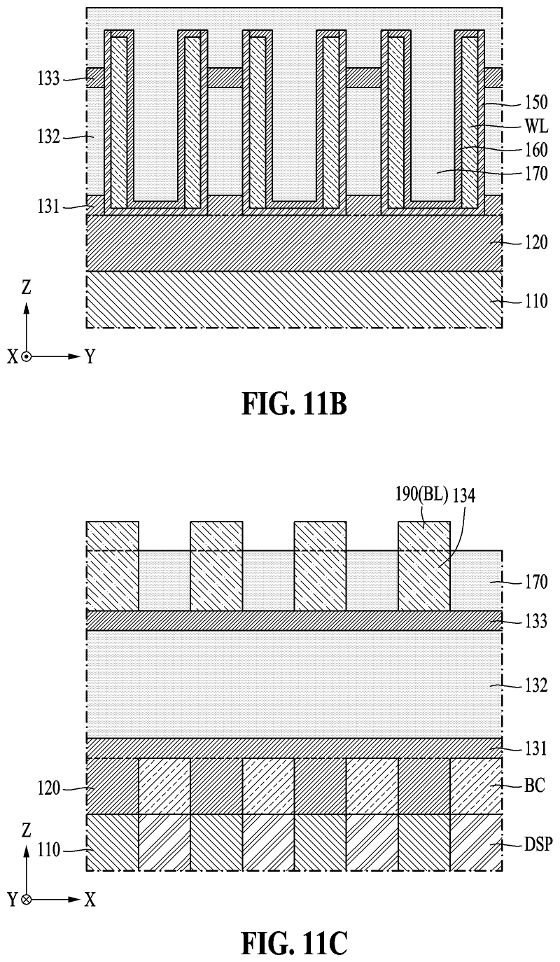

The mold structure 130 may be a mold pattern, which include a first silicon nitride pattern 131, a silicon oxide pattern 132, a second silicon nitride pattern 133, and a first metal layer 134. The silicon oxide pattern 132 may be disposed between the first silicon nitride pattern 131 and the second silicon nitride pattern 133, and the first metal layer 134 may be disposed on the second silicon nitride pattern 133, to form the mold structure 130. For example, the first silicon nitride pattern 131, the silicon oxide pattern 132, the second silicon nitride pattern 133, and the first metal layer 134 may be disposed sequentially from a lower end portion of the mold structure 130. The lower end portion of the first metal layer 134 may be disposed at a lower level than the upper end portion of the word line WL1. For reference, a plurality of mold structures 130 may be arranged in the first direction (e.g., Y-axis direction). For example, as shown in FIG. 11A, a plurality of mold structures 130 may be spaced apart from each other in the first direction (e.g., Y-axis direction).

The first metal layer 134 may be disposed within the mold structure 130. For example, the first metal layer 134 may be a part of the mold structure 130. The first metal layer 134 may be in contact with the first channel pattern 140. For example, the first metal layer 134 may be in contact with a side surface of the first channel pattern 140. The side surface of the first channel pattern 140 may be parallel to a X-Z plane. The first metal layer 134 may be conductive sub-mold patterns. The conductive sub-mold patterns 134 may be formed of or include doped polysilicon, a metal, a conductive metal nitride, a conductive metal silicide, a conductive metal oxide, or a combination thereof. The conductive sub-mold patterns 134 may be formed of doped polysilicon, Al, Cu, Ti, Ta, Ru, W, Mo, Pt, Ni, Co, TiN, TaN, WN, NON, TiAl, TiAlN, TiSi, TiSiN, TaSi, TaSiN, RuTiN, NiSi, CoSi, IrOx, RuOx, or a combination thereof, but the present invention is not limited thereto.

The second metal layer 190 may be disposed on the first metal layer 134, the first channel pattern 140, and the third insulating layer 170. The second metal layer 190 may be a bit line BL. The second metal layer 190 may extend in the first direction parallel to the substrate. The second metal layer 190 may be conductive bit line layer, which includes or is formed of doped polysilicon, a metal, a conductive metal nitride, a conductive metal silicide, a conductive metal oxide, or a combination thereof. The second metal layer 190 may be formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof, but the present invention is not limited thereto.

According to an embodiment, the first channel pattern 140 may have a plurality of surfaces, the first metal layer 134 may be in contact with a first surface among the plurality of surfaces, and the second metal layer 190 may be in contact with a second surface different from the first surface, among the plurality of surfaces.

According to an embodiment, the first metal layer 134 and the second metal layer 190 may include conductive materials of the same type as or a different type from each other. For example, the bit lines BL may be formed of the second metal layer 190. According to an embodiment, the conductive sub-mold pattern 134 and the bit line 190 may include or be formed of the same conductive material or the same combination of conductive materials as each other. According to another embodiment, the conductive sub-mold pattern 134 and the bit line 190 may include or be formed of different conductive material or different combinations of conductive materials from each other.

Each of the first channel patterns 140 and a corresponding one of the conductive sub-mold patterns may contact each other with a contact area, and the height CH of the contact area in Z-axis direction may exceed a thickness of the first channel pattern 140 in Y-direction.

According to an embodiment, the bit line BL may be formed of the second metal layer 190 disposed on the first channel pattern 140. For example, the second metal layer 190 may be bit lines BL formed on the first metal layer 134.

The bit line BL may extend in the first direction parallel to the substrate. The bit line BL may be formed in a direction (e.g., the first direction) orthogonal to the word line WL1 on the first channel pattern 140. For example, the bit line BL may extend across the word lines WL.

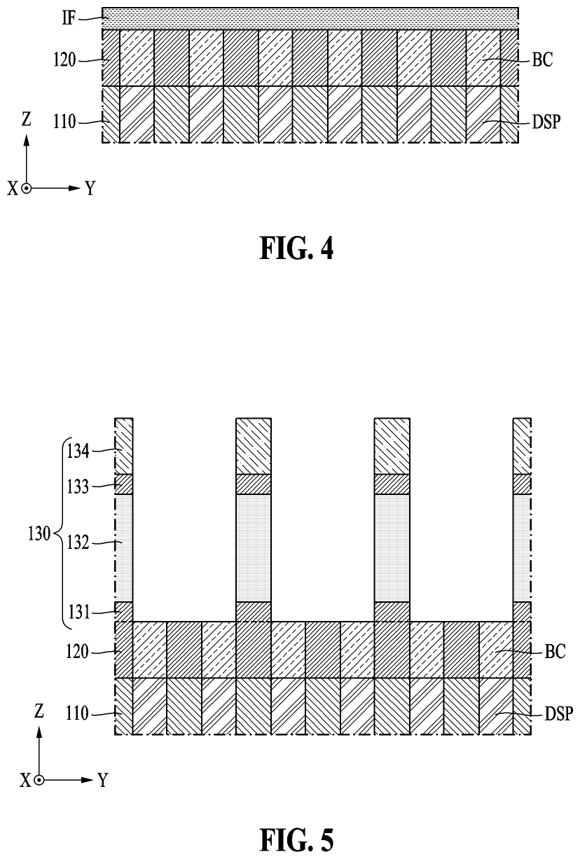

Hereinafter, FIGS. 4 to 12 are diagrams to describe a method of manufacturing the semiconductor device of FIG. 3.

Referring to FIG. 4, storage node contacts BC connected to data storage patterns DSP may be provided with a first insulating layer 120 and a lower insulating layer 110.

For example, the storage node contacts BC and the first insulating layers 120 may be formed such that the first insulating layer 120 is disposed between the storage node contacts BC. The data storage patterns DSP may be formed such that each of the storage node contacts BC is connected to a corresponding one of the data storage patterns DSP. The lower insulating layer 110 may be formed to be disposed between data storage patterns DSP.

In some embodiments, though not shown in the drawings, wiring layers and/or wiring patterns may be formed by using a back-end-of-line (BEOL) process on the data storage patterns DSP, after forming the data storage patterns DSP. Subsequently, the resultant structure (which include the storage node contacts BC, the data storage patterns DSP, the first insulating layer 120 and the lower insulating layer 110) may be flipped such that the storage node contacts BC face upward. The storage node contact BC and the first insulating layer 120 may be coated with an insulating film IF.

Referring to FIG. 5, a top surface of the first insulating layer 120 may be exposed through an etch process, by which the insulating film IF is removed at least partially. Mold structures 130 may be formed in a direction perpendicular to one surface (e.g., the top surface) of the first insulating layer 120 that is exposed. For example, in a cross-sectional view along a Y-Z plane, the mold patterns 130 may be formed on the first insulating layer 120 such that each of the mold patterns 130 has a height (in Z-axis direction), which is greater than its width (in X-axis direction), resulting in a rectangular shape. The mold structure 130 may include an insulating layer formed by a chemical vapor deposition (CVD) process. Each of the mold structures 130 may be a plurality of stacked patterns including the first silicon nitride pattern 131, the silicon oxide pattern 132, the second silicon nitride pattern 133, and the first metal layer 134. The first silicon nitride pattern 131 and the second silicon nitride pattern 133 may be formed of at least one of a silicon carbonitride (SiCN), a silicon carbon oxynitride (SiCON), or silicon nitride (SiN). The silicon oxide pattern 132 may include (or formed of) one of hafnium oxide (HfO), aluminum oxide (AlO), and tantalum oxide (TaO). In some embodiments, the first metal layer 134 may be a conductive sub-mold pattern which is formed of doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, or a combination thereof.

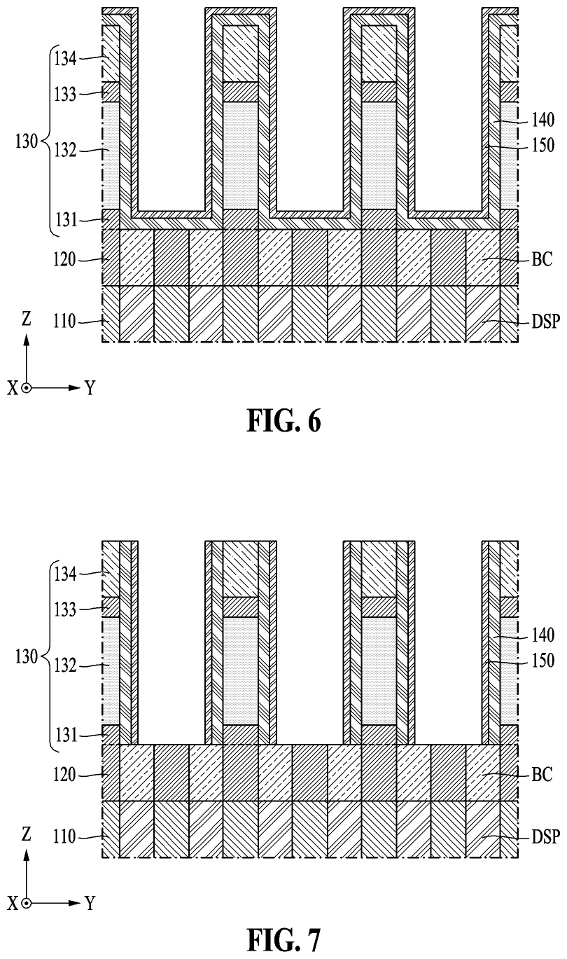

Referring to FIG. 6, the first channel layer 140 and the gate insulating layer 150 may be formed by a physical vapor deposition (PVD) process, a CVD process, or an atomic layer deposition (ALD) process. The first channel layer 140 may be formed on the mold structures 130, the first insulating layer 120 and the storage node contact BC between the mold structures 130. The gate insulating layer 150 may be formed on the first channel layer 140. For example, the first channel layer 140 and the gate insulating layer 150 may be sequentially formed on the mold structure 130.

Referring to FIG. 7, an upper surface of the first channel layer 140 may be subjected to an etch-back process, thereby forming first channel patterns. The top surface of the gate insulating layer 150 between mold structures 130 may be subjected to the etch-back process, thereby being partially removed.

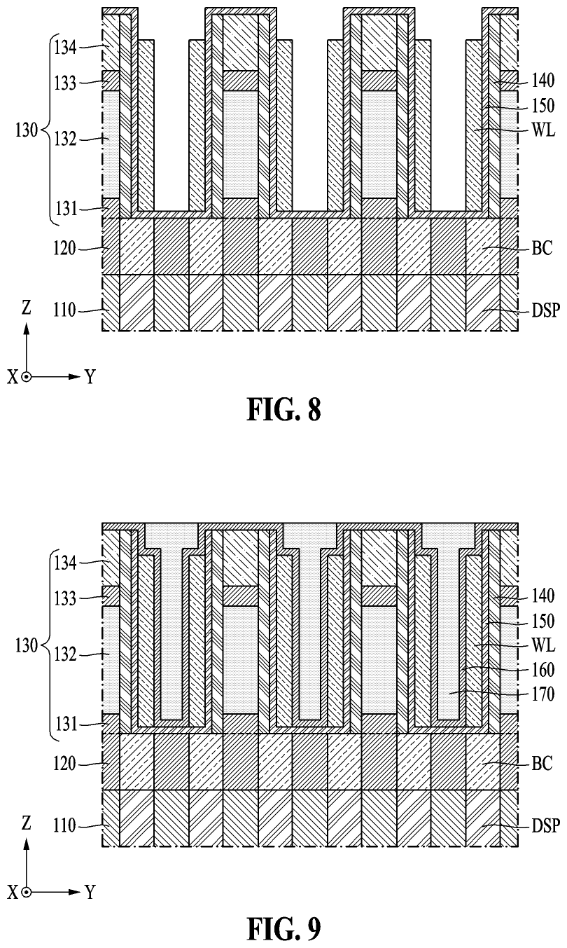

Referring to FIG. 8, the removed portion of the gate insulating layer 150 may be redeposited, and word line WL may be formed on the gate insulating layer 150. The first metal layer 134 may be included in the mold structure 130 such that a position level (heigh) of the mold structure 130 is increased, and accordingly, a position level (height) of the word line WL may also increase. The word line WL may include or be formed of a conductive material. In some embodiments, the word line WL may include an insulating material. Chamfering of the word line WL may be performed by a wet etch process.

Referring to FIG. 9, second insulating layer 160 may be deposited on the word line WL, and a third insulating layer 170 may be formed on the second insulating layer 160. The second insulating layer 160 may be formed of a silicon nitride, and the third insulating layer 170 may be formed of a silicon oxide. When (or before) the second insulating layer 160 and the third insulating layer 170 are formed, the entire top surface may be planarized by a chemical mechanical polishing (CMP) process, and the top surface of each of the mold structure 130 may be exposed, thereby forming gate insulating patterns 150 and the first channel patterns 140.

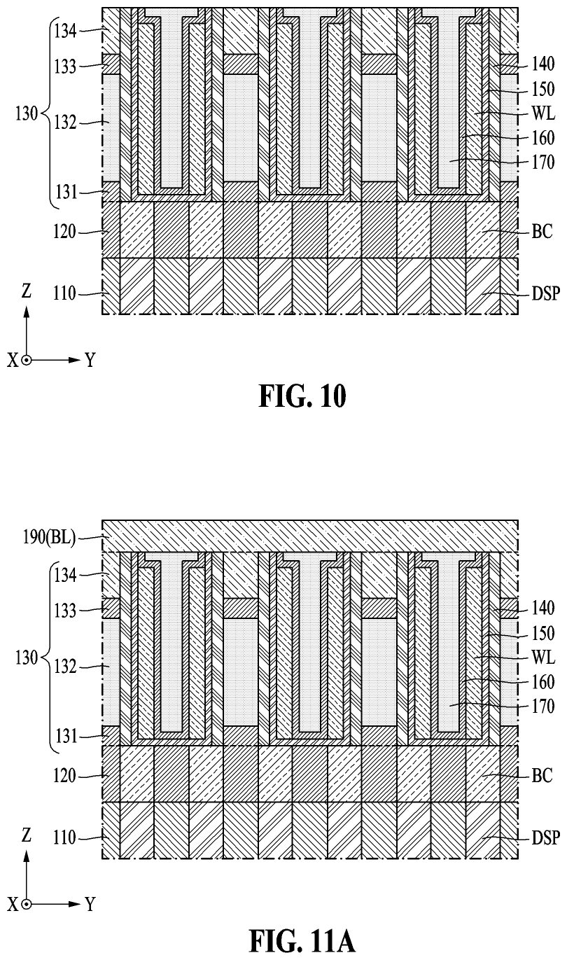

Referring to FIG. 10, upper portions of the first channel pattern 140, the second insulating layer 160, and the third insulating layer 170 may be exposed by an etch-back process, and/or an oxide deposition process and a CMP process may be performed. As a result, the second insulating layer 160 may separate into a plurality of segments. During the etch-back process, upper portions of the first channel pattern 140, the gate insulating patterns 150, the second insulating layer 160, the third insulating layer 170 and the first metal layer 134 may be partially removed.

Referring to FIGS. 11A, 11B and 11C, a second metal layer 190 may be deposited on the first channel pattern 140. The second metal layer 190 may be a bit line BL. The bit line 190 (BL) may be formed of or include a conductive material that is the same as or different from that of the conductive sub-mold patterns 134.

FIG. 11B is a diagram illustrating a portion of a cross section taken along line B-B′ of FIG. 2. An upper end portion of the word line WL may be disposed at a higher level than a lower end portion of the second silicon nitride pattern 133.

FIG. 11C is a diagram illustrating a portion of a cross section taken along line C-C′ of FIG. 2. The first metal layer 134 and the second metal layer 190 may be disposed to protrude further upward than the second silicon nitride pattern 133. For example, the first metal layer 134 and the second metal layer 190 may be positioned higher than the second silicon nitride pattern 133.

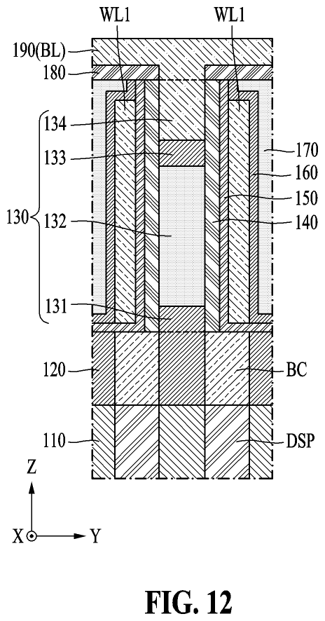

FIG. 12 is a cross-sectional view illustrating another example of a semiconductor device according to an embodiment. FIG. 12 illustrates a cross section (e.g., a cross section corresponding to a Y-Z plane) obtained by cutting a memory cell of the semiconductor device in a direction perpendicular to a substrate along line A-A′ of FIG. 2.

The semiconductor device 100 may include a data storage pattern DSP, a storage node contact BC, a first insulating layer 120, a second insulating layer 160, a third insulating layer 170, a mold structure 130, a first channel pattern 140, a gate insulating pattern 150, a first metal layer 134, a second metal layer 190, a word line WL1, a bit line BL, and a second channel pattern 180.

The second channel pattern 180 may extend in the first direction from one end of the first channel pattern 140.

According to an embodiment, the first channel pattern 140 and the second channel pattern 180 may include semiconductor oxides of the same type as or a different type from each other. The semiconductor oxides may include or be any one or any combination of IGZO, InxO, ZnxO, SnxO, InxZnyO, InxSnyZnzO, AlxZnySnzO, YbxGayZnzO, and HfxInyZnzO, but the present invention is not limited thereto. For example, the first channel pattern 140 may be formed of an indium gallium zinc oxide (IGZO), and the second channel pattern 180 may be formed of an indium tin oxide (ITO). The semiconductor oxide may include high proportions of some elements. For example, the IGZO may be a gallium (Ga)-rich IGZO, and at least one of the first channel pattern 140 or the second channel pattern 180 may include a Ga-rich IGZO.

According to an embodiment, the first metal layer 134 and the second metal layer 190 may include conductive materials of the same type as or a different type from each other.

According to an embodiment, the bit line BL may be formed of the second metal layer 190. For example, the second metal layer 190 may include or be formed of a conductive material and may be formed on the first metal layer 134.

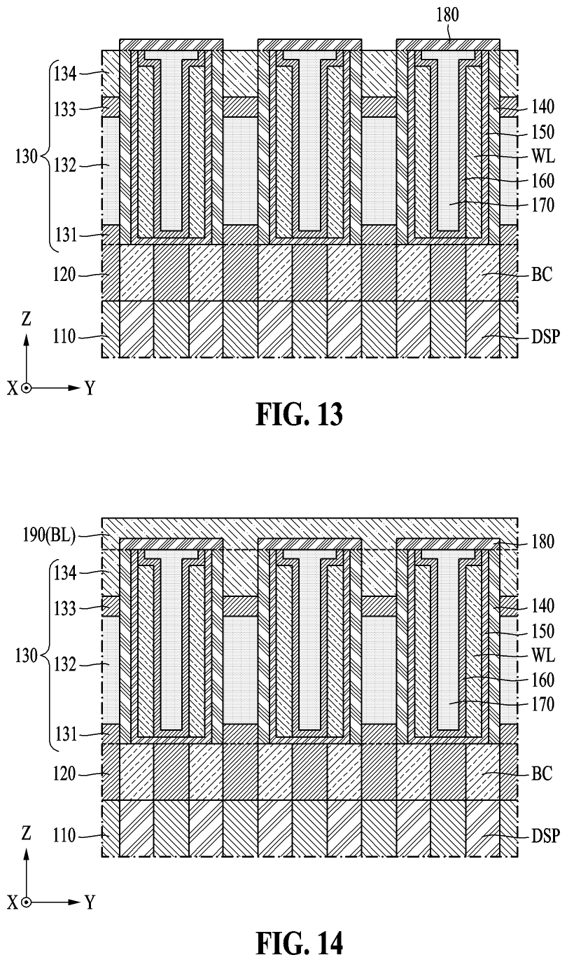

Hereinafter, FIGS. 13 and 14 are diagrams to describe a method of manufacturing the semiconductor device of FIG. 12.

The description provided with reference to FIGS. 4 to 9 may equally apply to the method of manufacturing the semiconductor device of FIG. 12. For example, the same process steps as those described with reference to FIGS. 4 to 9 may be performed. Subsequently, referring to FIG. 13, upper portions of the first channel pattern 140, the second insulating layer 160, and the third insulating layer 170 may be exposed by an etch-back process, and/or an oxide deposition process and a CMP process may be performed. As a result, the second insulating layer 160 may separate into a plurality of segments. During the etch-back process, upper portions of the first channel pattern 140, the gate insulating patterns 150, the second insulating layer 160, the third insulating layer 170 and the first metal layer 134 may be partially removed. A second channel layer 180 may be deposited on a surface exposed through the etch-back process. A portion of the second channel layer 180, which is located on a top surface of the first metal layer 134, may be removed by cutting (removed), thereby forming second channel patterns. An upper portion of the second channel pattern 180 may protrude further upward than the first metal layer 134. Referring to FIG. 14, a second metal layer 190 may be formed (or deposited) on the first channel pattern 140. The second metal layer 190 may be a bit line BL. The bit line 190 (BL) may be formed of or include a conductive material that is the same as or different from that of the conductive sub-mold patterns 134. The second channel pattern 180 may extend in the first direction from one end of the first channel pattern 140.

According to an embodiment, the first channel pattern 140 and the second channel pattern 180 may include semiconductor oxides of the same type as or a different type from each other.

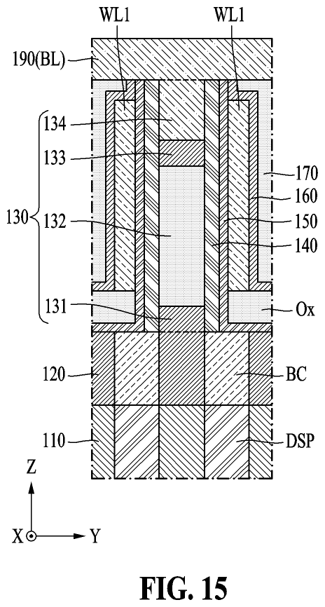

FIG. 15 is a cross-sectional view illustrating another example of a semiconductor device according to an embodiment. FIG. 15 illustrates a cross section (e.g., a cross section corresponding to a Y-Z plane) obtained by cutting a memory cell of the semiconductor device in a direction perpendicular to a substrate along line A-A′ of FIG. 2.

The semiconductor device 100 may include a data storage pattern DSP, a storage node contact BC, a first insulating layer 120, a second insulating layer 160, a third insulating layer 170, a mold structure 130, a first channel pattern 140, a gate insulating pattern 150, a first metal layer 134, a second metal layer 190, a word line WL1, a bit line BL, and an oxide layer Ox.

The oxide layer Ox may include or be formed of oxide of at least one selected from nickel (Ni), titanium (Ti), vanadium (V), iron (Fe), chromium (Cr), cobalt (Co), hafnium (Hf), and tantalum (Ta). For example, the oxide layer Ox may include or be formed of titanium oxide (TiO). The oxide layer Ox may be disposed directly on a lower end portion of the word line WL, and may be in contact with one side surface of each of the gate insulating pattern 150 and the second insulating layer 160. The oxide layer Ox may be included in a space between the lower end portion of the word line WL and the storage node contact BC, to supplement the reliability of the semiconductor device.

It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact.

According to an embodiment, the second channel pattern 180 may extend in the first direction from one end of the first channel pattern 140.

According to an embodiment, the first channel pattern 140 and the second channel pattern 180 may include semiconductor oxides of the same type as or a different type from each other. The semiconductor oxides may include or be any one or any combination of IGZO, InxO, ZnxO, SnxO, InxZnyO, InxSnyZnzO, AlxZnySnzO, YbxGayZnzO, and HfxInyZnzO, but the present invention is not limited thereto. For example, the first channel pattern 140 may be formed of an IGZO, and the second channel pattern 180 may be formed of an ITO. The semiconductor oxide may include high proportions of some elements (high concentrations of certain elements). For example, the IGZO may be a Ga-rich IGZO, and at least one of the first channel pattern 140 or the second channel pattern 180 may include a Ga-rich IGZO.

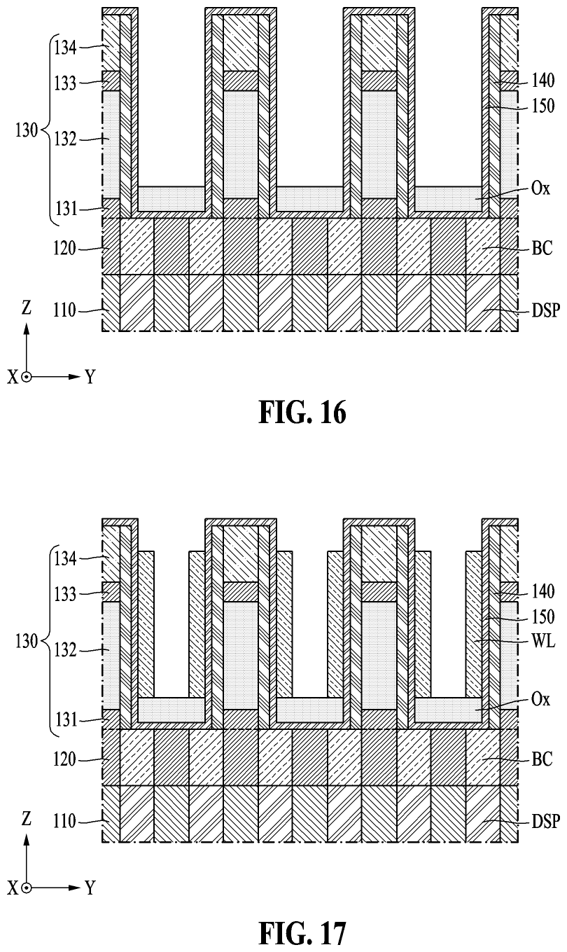

Hereinafter, FIGS. 16 to 20 are diagrams to describe a method of manufacturing the semiconductor device of FIG. 15.

The description provided with reference to FIGS. 4 to 7 may equally apply to the method of manufacturing the semiconductor device of FIG. 15. For example, the same process steps as those described with reference to FIGS. 4 to 7 may be performed.

Referring to FIG. 16, the removed portion of the gate insulating layer 150 may be redeposited, and the oxide layer Ox may be formed on the gate insulating layer 150 and between mold structures 130. The oxide layer Ox may include or be formed of oxide of at least one selected from nickel (Ni), titanium (Ti), vanadium (V), iron (Fe), chromium (Cr), cobalt (Co), hafnium (Hf), and tantalum (Ta), and may be formed by an ALD process.

Referring to FIG. 17, the word line WL may be formed on the oxide layer Ox. The word line WL may include a conductive material. Chamfering of word lines WL1 and WL2 may be performed by a wet etch process. The oxide layer Ox may be positioned in the lower end portion of the word line WL.

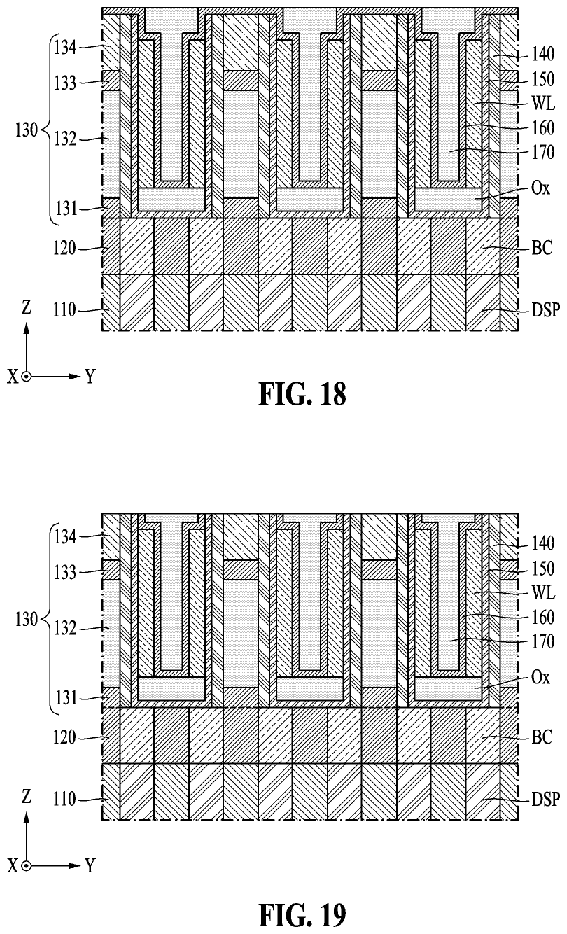

Referring to FIG. 18, second insulating layer 160 may be deposited on the word line WL, and a third insulating layer 170 may be formed on the second insulating layer 160. The second insulating layer 160 may be formed of a silicon nitride, and the third insulating layer 170 may be formed of a silicon oxide. When (or before) the second insulating layer 160 and the third insulating layer 170 are formed, the entire top surface may be planarized by a CMP process, and the top surface of each of the mold structure 130 may be exposed, thereby forming gate insulating patterns 150 and the first channel patterns 140.

Referring to FIG. 19, upper portions of the first channel pattern 140, the second insulating layer 160, and the third insulating layer 170 may be exposed by an etch-back process, and/or an oxide deposition process and a CMP process may be performed. As a result, the second insulating layer 160 may separate into a plurality of segments.

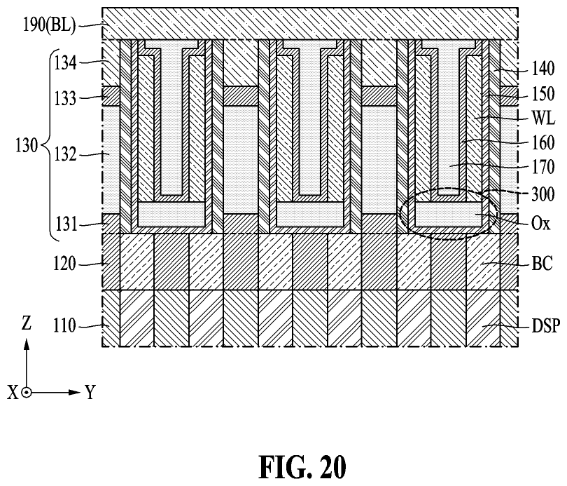

Referring to FIG. 20, a second metal layer 190 may be deposited on the first channel pattern 140. The second metal layer 190 may be a bit line BL. The bit line 190 (BL) may be formed of or include a conductive material that is the same as or different from that of the conductive sub-mold patterns 134.

A region 300 of FIG. 20 represents a structure in which the oxide layer Ox is deposited in a lower end portion of the word line WL.

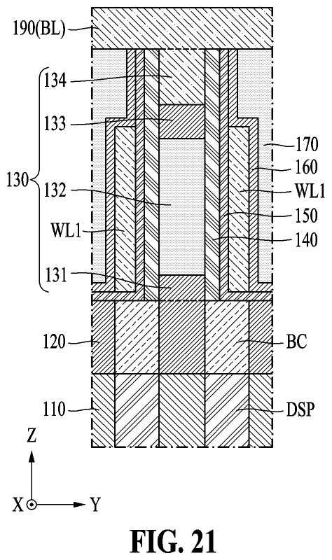

FIG. 21 is a cross-sectional view illustrating another example of a semiconductor device according to an embodiment. FIG. 21 illustrates a cross section (e.g., a cross section corresponding to a Y-Z plane) obtained by cutting a memory cell of the semiconductor device in a direction perpendicular to a substrate along line A-A′ of FIG. 2.

Referring to FIG. 21, a lower end portion of a first metal layer 134 may be disposed at a higher level than an upper end portion of a word line WL1. A position level of the word line WL1 may be lower than a level of the lower end portion of the first metal layer 134, and accordingly, a bit line BL and the word line WL1 may form an underlap structure. According to an aspect of the invention, a time-dependent dielectric breakdown (TDDB) (which may occur during operating of a semiconductor device, when a high voltage continues to be applied) may be reduced by the underlap structure, e.g., by lowering the position level of the word line WL1.

According to an embodiment, the second channel pattern 180 may extend in the first direction from one end of the first channel pattern 140.

According to an embodiment, the first channel pattern 140 and the second channel pattern 180 may include semiconductor oxides of the same type as or a different type from each other. The semiconductor oxides may include or be formed of any one or any combination of IGZO, InxO, ZnxO, SnxO, InxZnyO, InxSnyZnzO, AlxZnySnzO, YbxGayZnzO, and HfxInyZnzO, but the present invention is not limited thereto. For example, the first channel pattern 140 may be formed of an IGZO, and the second channel pattern 180 may be formed of an ITO. The semiconductor oxide may include high proportions of some elements. For example, the IGZO may be a Ga-rich IGZO, and at least one of the first channel pattern 140 or the second channel pattern 180 may include a Ga-rich IGZO.

According to an embodiment, the first channel pattern 140 may have a plurality of surfaces, the first metal layer 134 may be in contact with a first surface among the plurality of surfaces, and the second metal layer 190 may be in contact with a second surface different from the first surface, among the plurality of surfaces.

According to an embodiment, the first metal layer 134 and the second metal layer 190 may include conductive materials of the same type as or a different type from each other.

A contact area between the first channel pattern 140 and each of the first metal layer 134 and the second metal layer 190 may exceed a thickness of the first channel pattern 140. For example, each of the first channel patterns 140 and a corresponding one of the conductive sub-mold patterns may contact each other with a contact area, and the height of the contact area in Z-axis direction may exceed a thickness of the first channel pattern 140 in Y-direction.

According to an embodiment, the bit line BL may be formed of the second metal layer 190. For example, the second metal layer 190 may include or be formed of a conductive material and may be formed on the first metal layer 134.

According to an embodiment, an oxide layer may be further provided on the lower end portion of the word line WL1.

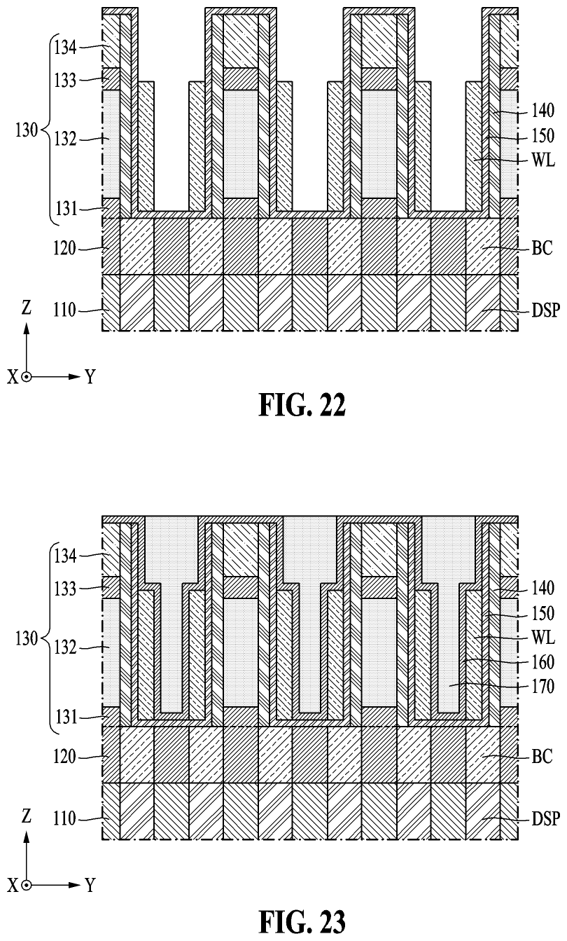

Hereinafter, FIGS. 22 to 25 are diagrams to describe a method of manufacturing the semiconductor device of FIG. 21.

The description provided with reference to FIGS. 4 to 7 may equally apply to the method of manufacturing the semiconductor device of FIG. 21. For example, the same process steps as those described with reference to FIGS. 4 to 7 may be performed.

Referring to FIG. 22, the removed portion of the gate insulating layer 150 may be redeposited, and word lines WL may be formed on the gate insulating pattern 150. the word lines WL may include or be formed of a conductive material. In some embodiments, the word line WL may include an insulating material. Chamfering of the word line WL may be performed by a wet etch process. The word lines WL may be formed such that a position level of the word line WL is reduced through the chamfering process.

Referring to FIG. 23, second insulating layer 160 may be deposited on the word line WL, and a third insulating layer 170 may be formed on the second insulating layer 160. The second insulating layer 160 may be formed of a silicon nitride, and the third insulating layer 170 may be formed of a silicon oxide. When (or before) the second insulating layer 160 and the third insulating layer 170 are formed, the entire top surface may be planarized by a CMP process, and the top surface of each of the mold structure 130 may be exposed, thereby forming gate insulating patterns 150 and the first channel patterns 140.

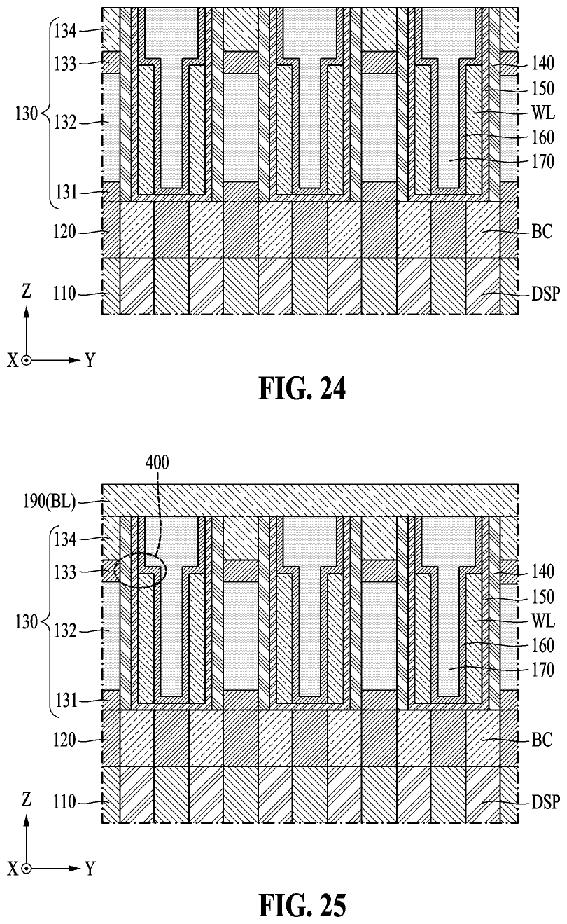

Referring to FIG. 24, upper portions of the first channel pattern 140, the second insulating layer 160, and the third insulating layer 170 may be exposed by an etch-back process, and/or an oxide deposition process and a CMP process may be performed. As a result, the second insulating layer 160 may separate into a plurality of segments.

Referring to FIG. 25, a second metal layer 190 may be deposited on the first channel pattern 140. The second metal layer 190 may be a bit line BL. The bit line 190 (BL) may be formed of or include a conductive material that is the same as or different from that of the conductive sub-mold patterns 134.

As shown in a region 400 of FIG. 25, the lower end portion of the first metal layer 134 may be disposed at a higher level than an upper end portion of the word line WL.

It should be appreciated that certain embodiments of the present disclosure and the terms used therein are not intended to limit the technological features set forth herein to particular embodiments and include various changes, equivalents, or replacements for a corresponding embodiment.

It is to be understood that descriptions of a singular form of a noun corresponding to an item may refer to one or more of the things, unless the relevant context clearly indicates otherwise.

As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases.

As used herein, such terms as “1st” and “2nd,” or “first” and “second” may be used to simply distinguish a corresponding component from another, and does not limit the components in other aspects (e.g., importance or order) unless context indicates otherwise. In addition, a term that is referenced with a particular ordinal number (e.g., “first”) in a particular claim may be described elsewhere with a different ordinal number (e.g., “second”) in the specification or another claim.

Unless otherwise defined, all terms including technical and scientific terms used herein have the same meaning as commonly understood by one of ordinary skill in the art to which embodiments belong. Terms, such as those defined in commonly used dictionaries, are to be interpreted as having a meaning that is consistent with their meaning in the context of the relevant art and the present disclosure, and are not to be interpreted in an idealized or overly formal sense unless expressly so defined herein.

When describing the embodiments with reference to the accompanying drawings, like reference numerals refer to like components and a repeated description related thereto may be omitted. In the description of embodiments, detailed description of well-known related structures or functions may be omitted when it is deemed that such description will cause ambiguous interpretation of the present disclosure.

Effects which can be acquired by the invention are not limited to the effects described above, and other effects that have not been mentioned can be clearly understood by one of the ordinary in the art from the present disclosure.

What is claimed is:

1. A semiconductor device comprising:
a bit line extending in a first direction parallel to a substrate;
a first channel pattern connected to the bit line and disposed perpendicular to the substrate;
a gate insulating pattern disposed on the first channel pattern;
a word line disposed on the gate insulating pattern and extending in a second direction that is parallel to the substrate and perpendicular to the first direction;
data storage patterns spaced apart from each other in the first direction and the second direction;
storage node contacts, each of which is disposed on a corresponding one of the data storage patterns; and
a mold pattern extending in the second direction and configured to support the first channel pattern,
wherein, the mold pattern includes a conductive sub-mold pattern.

2. The semiconductor device of claim 1, wherein the bit line is formed of a conductive bit line layer and disposed on the first channel pattern.

3. The semiconductor device of claim 1, wherein an upper end portion of the word line is disposed at a higher level than a lower end portion of the conductive sub-mold pattern.

4. The semiconductor device of claim 2, wherein:
the first channel pattern has a plurality of surfaces,
the conductive sub-mold pattern is in contact with a first surface among the plurality of surfaces,
the conductive bit line layer is in contact with a second surface among the plurality of surfaces, and
the second surface is different from the first surface.

5. The semiconductor device of claim 4, wherein the conductive sub-mold pattern and the conductive bit line layer are formed of the same metal as each other.

6. The semiconductor device of claim 1, further comprising a second channel pattern extending in the first direction from one end of the first channel pattern.

7. The semiconductor device of claim 6, wherein the second channel pattern and the first channel pattern are formed of the same semiconductor oxide material.

8. The semiconductor device of claim 1, further comprising an oxide layer disposed directly on a lower end portion of the word line.

9. The semiconductor device of claim 1, wherein an upper end portion of the word line is disposed at a lower level than a lower end portion of the conductive sub-mold pattern.

10. A method of manufacturing a semiconductor device, the method comprising:
preparing a storage node contact connected to a data storage pattern;
forming a mold pattern positioned lengthwise in a first direction, the mold pattern comprising a conductive sub-mold pattern;
forming a first channel pattern on the mold pattern;
forming a gate insulating layer on the mold pattern;
partially removing the gate insulating layer disposed on the mold pattern and a top surface of the first channel pattern, thereby forming a gate insulating pattern;
forming a word line on the gate insulating pattern, the word line extending in a second direction which is perpendicular to the first direction;
forming a second insulating layer and a third insulating layer on the word line;
performing a planarization thereby partially removing the second insulating layer and the third insulating layer and exposing the top surface of the first channel pattern and the mold pattern; and
forming a bit line by depositing a conductive bit line layer on the first channel pattern.

11. The method of claim 10, further comprising after the top surface of the first channel pattern and the mold pattern is exposed, forming a second channel pattern extending in a third direction, wherein the bit line is extending in the third direction, and the third direction is perpendicular to the first direction and the second direction.

12. The method of claim 11, wherein the second channel pattern and the first channel pattern are formed of the same semiconductor oxide material.

13. The method of claim 10, further comprising, prior to the forming of the word line, disposing an oxide layer on the storage node contact and the data storage pattern.

14. A semiconductor device comprising:
a bit line extending in a first direction parallel to a substrate;
a word line extending in a second direction perpendicular to the first direction;
a storage node contact connected to the word line;
a data storage pattern connected to a lower portion of the storage node contact;
a mold pattern extending in the second direction, the mold pattern comprising a conductive sub-mold pattern;
a first channel pattern disposed on the mold pattern; and
a gate insulating pattern disposed on the first channel pattern,
wherein the bit line is formed of a conductive bit line layer disposed in the first direction.

15. The semiconductor device of claim 14, further comprising a second channel pattern extending in the first direction from one end of the first channel pattern.

16. The semiconductor device of claim 15, wherein:
the first channel pattern has a plurality of surfaces,
the conductive sub-mold pattern is in contact with a first surface among the plurality of surfaces,
the conductive bit line layer is in contact with a second surface among the plurality of surfaces, and
the second surface is different from the first surface.

17. The semiconductor device of claim 14, wherein the first channel pattern is disposed at a higher level than an upper end portion of the word line.

18. The semiconductor device of claim 14, wherein an upper end portion of the word line is disposed at a higher level than a lower end portion of the conductive sub-mold pattern.

19. The semiconductor device of claim 14, further comprising an oxide layer disposed on a lower end portion of the word line.

20. The semiconductor device of claim 15, wherein the second channel pattern and the first channel pattern are formed of the same semiconductor oxide material.
